(19) United States
(12) Patent Application Publication
(10) Pub. No.: US 2007/0235870 A1
(43) Pub. Date: Oct. 11, 2007

(54) Common Assembly Substrate and Applications Thereof

(75) Inventor: Guo-Cheng Liao, Meinong Town (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ADVANCED SEMICONDUCTOR ENGINEERING INC., Kaohsiung (TW)

(21) Appl. No.: 11/567,274

(22) Filed: Dec. 6, 2006

(30) Foreign Application Priority Data
Apr. 10, 2006 (TW) 95112729

(51) Int. Cl. H01L 23/48

(52) U.S. Cl. 257/734

(57) ABSTRACT

A common assembly substrate for carrying a die and applying the mechanisms are provided, wherein the common assembly substrate comprises a plurality of bonding fingers formed on one side of the substrate. A bonding wire is used to electrically connect the die with one of the bonding fingers, wherein at least two of the bonding fingers are located in the direction of the bonding wire.

### RELATED APPLICATIONS

The present application is based on, and claims priority from, Taiwan Application Serial Number 95112729, filed Apr. 10, 2006, the disclosure of which is hereby incorporated by reference herein in its entirety.

### FIELD OF THE INVENTION

The present invention relates to a semiconductor package, and more particularly to a common assembly substrate of a semiconductor package.

### BACKGROUND OF THE INVENTION

A semiconductor package process comprises attaching and electrically connecting dies onto a substrate, such as a chip carrier, via die bonding and wire bonding steps, and then encapsulating and cutting the bonded substrate to form a semiconductor package device.

FIG. 1 illustrates a top view of a semiconductor package. The semiconductor package comprises a substrate 100 a die 102 attached electrically connected to the substrates 100. The substrate 100 shown in FIG. 1 for example is a ball grid array (BGA) substrate. Each bonding wires 106 connects the die 102 with a bonding finger 104a, wherein the bonding fingers 104a are portions of interconnects exposed by a plurality of slits formed on a solder mask of the substrate 100. The other end of the interconnect wires of the substrate 100 is attached with a solder ball (not shown) by which the die 102 can be connected to an external electrical device.

A conventional BGA substrate 100 is designed to be reserved for the use of a specific die. Arrangement of bonding fingers 104a set on the conventional BGA substrate 100 is designed to correspond with features of a specific die 102. For example, each bonding pad 101 of the die 102 has a bonding finger 104a of the BGA substrate 100 associated therewith. The conventional BGA substrate 100 can match the specific die 102 very well by virtue of the advantage of this design.

However, since the lifecycle of an electronic device is shorter than ever. The manufacturer should provide large varieties of chip packages with a specific circuit layout. Since a conventional substrate is reserved for the use of a specific die (chip), the manufacturer should provide various substrates for satisfying these varieties of chip package. The manufacturer should bear additional cost for preparing various molds of these different substrates. Accordingly, it is not economical to apply the conventional substrates. The date of delivery may be out of control due to the increasing process complexity in manufacturing large varieties of chip package.

### SUMMARY OF THE INVENTION

It is desirable, therefore, to provide a common assembly substrate that is available for a plurality chip package types to reduce the manufacturing cost and to enhance the performance of manufacturing process.

The object of the present invention is to provide a common assembly substrate for carrying a die. The common assembly substrate comprises a plurality of bonding fingers formed on one side of the common assembly substrate. A bonding wire is used to electrically connect a bonding pad of the die with one of these bonding fingers, wherein at least two of the bonding fingers are intersected by the extension of the bonding wire directed from the die.

Another object of the present invention is to provide package structure comprising a die, a common assembly substrate, a plurality of bonding fingers, and a bonding wire. The common assembly substrate is used for carrying the die. These bonding fingers are formed on one side of the common assembly substrate. The bonding wire is used to electrically connect a bonding pad of the die with one of these bonding fingers, wherein at least two of the bonding fingers are intersected by the extension of the bonding wire directed from the die.

In accordance with the aforementioned embodiments of present invention, the features of the present invention provide a common assembly substrate available for a plurality of chip package types to substitute the conventional substrate that is reserved for the use of a specific die. Whereby applying the present common assembly substrate can significantly reduced the manufacturing cost, and enhance the performance of manufacture process so as to resolve the prior problems of cost increase and delay of product delivery.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a top view of a semiconductor package.

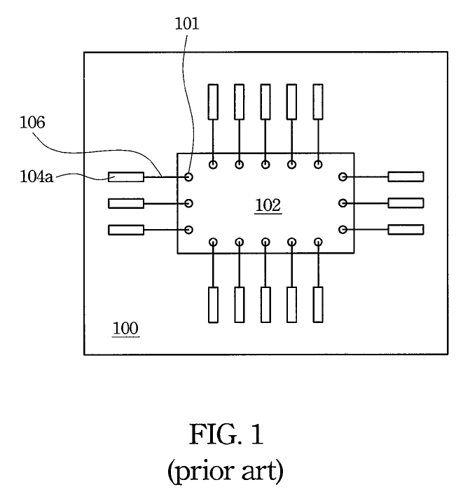

FIG. 2A illustrates a BGA package structure 20 in accordance with a preferred embodiment of the present invention.

FIG. 2B illustrates a top view of the BGA package 20 structure shown in FIG. 2A.

FIG. 3 illustrates another BGA package structure 30 in accordance with another preferred embodiment of the present invention.

### DETAILED DESCRIPTION OF THE PREFERRED EMBODIMENT

The objectives of the present invention is to provide a common assembly substrate that is available for a plurality of types of die to satisfy various designs of chip package so as to resolve the prior problems of cost increase and delay of product delivery.

The foregoing aspects and many of the attendant advantages of this invention will become better understood by reference to the following embodiments that are embodied as a BGA package structure.

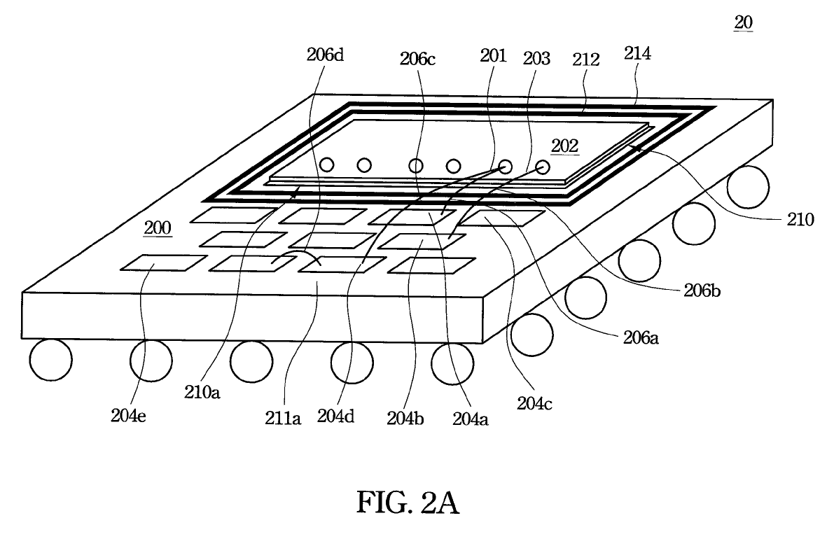

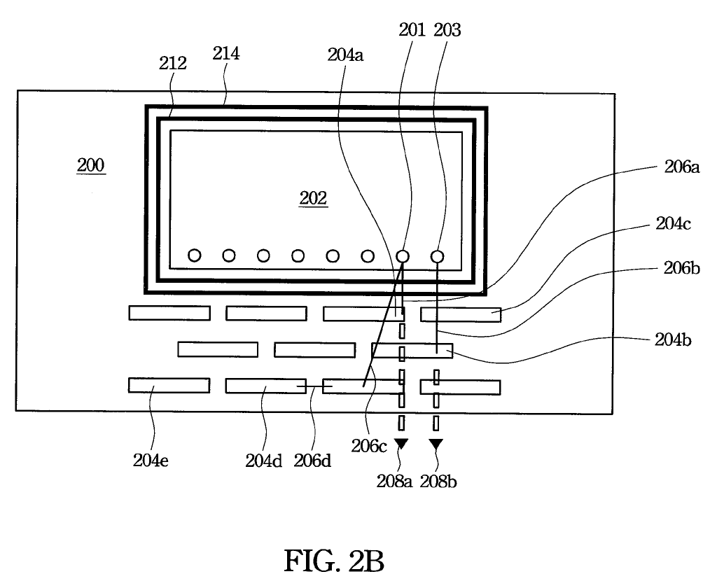

FIG. 2A illustrates a BGA package structure 20 in accordance with a preferred embodiment of the present invention. FIG. 2B illustrates a top view of the BGA package structure 20 shown in FIG. 2A. The BGA package structure 20 comprises a die 202 and a common assembly substrate 200 used to carry the die 202. The common assembly substrate comprises a die attaching area 210 and a plurality of conductive wires (not shown).

The die attaching area 210 attaches and carries the die 202 that is set on the surface of the common assembly substrate 200 beneath the die 202. In the present embodiment of the present invention the die attaching area 210 is a fictitious area. For example, in the present embodiment the die attaching area 210 is shown as the area beneath the die 202.

The conductive wires are interconnected to form in the common assembly substrate 200. One end of each conductive wire is exposed by a slit formed on the solder mask of common assembly substrate 200. The exposed portions of the conductive wires are indicated as bonding fingers 204a, 204b, 204c, 204d and 204e. In the present embodiment, the bonding fingers 204a, 204b, 204c, 204d and 204e are defined by five rectangular pads formed on the same side of the common assembly substrate 200 and arranged in a staggered matrix along a predetermined extension direction of the bonding fingers 204a, 204b, 204c, 204d and 204e.

Each of the bonding fingers 204a, 204b, 204c, 204d and 204e is adjacent to one edge 210a of the die attaching area 210, and is separated from the edge 210a of the die attaching area 210. In some embodiment of the present invention, the bonding fingers are parallel with one another, and the extension of the bonding fingers form an included angle with the edge 210a of the die attaching area 210 is in the range from about 15° to 165°. However in the present embodiment the bonding fingers 204a, 204b, 204c, 204d and 204e are parallel to the edge 210a of the die attaching area 210.

In the preferred embodiment of the present invention, the common assembly substrate 200 further comprises a power ring 212 and a ground ring 214, wherein the power ring 212 and the ground ring 214 are respectively formed between the die attaching area 210 and the parallel bonding fingers 204a, 204b, 204c, 204d and 204e, and are separated from the die attaching area 210 and the bonding fingers 204a, 204b, 204c, 204d and 204e. However in some embodiments of the present invention, the common assembly substrate 200 has no power ring and no ground ring set thereon, since the functions of the power ring 212 and the ground ring 214 may be respectively substitute by two of the bonding fingers 204a, 204b, 204c, 204d and 204e.

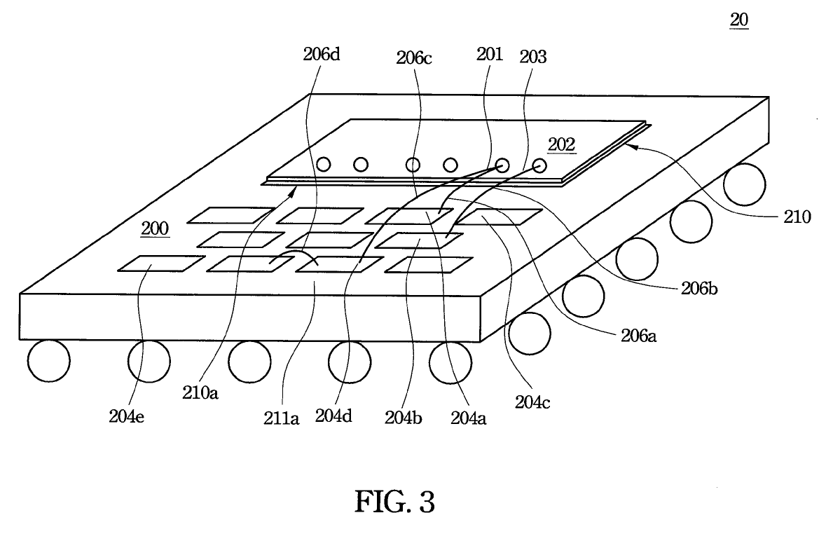

Refer to FIG. 3. FIG. 3 illustrates another BGA package structure 30 in accordance with another preferred embodiment of the present invention. In the present embodiment, the bonding finger 204d of the common assembly substrate 300 can perform the function provided by a power ring, and the bonding finger 204e can perform the function provided by a ground ring

Bonding wire is used to electrically connect a bonding pad of the die 202 with one of the bonding fingers, and at least two bonding fingers are intersected by the extension of the bonding wire directed from the die. For example, the first bonding wire 206a is used to electrically connect the bonding finger 204a with the bonding finger 204a, and at least two bonding fingers 204a and 204b are intersected by the extension (with reference to the arrow 208a) of the first bonding wire 206a. The second bonding wire 206b is used to electrically connect the bonding finger 204b with the bonding finger 204a, and at least two bonding fingers 204b and 204c are intersected by the extension (with reference to the arrow 208b) of the first bonding wire 206b.

Note that in some embodiments of the present invention, a single bonding finger can electrically connect to more than one bonding pad of the die via several wires. The connection between the bonding wires, the bonding pads and the bonding fingers is designed in accordance with the circuit layout patterned on the die 202. Thus the first bonding wire 206a and the second bonding wire 206b may either connect to the same bonding finger or respectively connect to different bonding fingers. In some embodiments of the present invention a single bonding pad can electrically connect to more than one bonding finger of the die via several wires. For example, the first bonding pad 201 electrically connects to the bonding finger 204d and 204e respectively via the first bonding wire 206a and the third bonding wire 206c.

To make do with the circuit layout design on a specific die, in some embodiment of the present invention each of two bonding fingers can be connected by a bonding wire. For example the fourth bonding wire 206d connects the bonding finger 204d with the bonding finger 204e.

In accordance with the aforementioned embodiments of present invention, the features of the present invention is to provide a common assembly substrate available for a plurality of chip package types to substitute the conventional substrate that is reserved for the use of a specific die. The present common assembly substrate comprises at least two bonding fingers that are intersected by the extension of a bonding wire directed from a die that is carried by the common assembly substrate, whereby the present common assembly substrate can make do with various dies having different circuit layouts. It is not necessary to develop a specific mold or processing steps for preparing an individual die. Thus applying the present common assembly substrate not only can significantly reduce the manufacturing cost but also can enhance the performance of the manufacture process.

Accordingly, the features of the present invention indeed provide a common assembly substrate available for a plurality of chip package types so as to resolve the prior problems of cost increase and delay of product delivery, and to confront the industry trends in shorting product lifecycle and demanding large product variety but ordering small quantity

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A common assembly substrate for carrying a die comprising:
a plurality of bonding fingers formed on one side of the common assembly substrate, wherein one of the bonding fingers is electrically connected to a first bonding pad set on the die by a first bonding wire, and at least two of the bonding fingers are respectively intersected with a predetermined extension direction of the first bonding wire extended from the die.

2. The common assembly substrate according to claim 1, further comprising a second bonding wire, wherein at least two of the bonding fingers are respectively intersected with a predetermined extension direction of the second bonding wire extended from the die.

3. The common assembly substrate according to claim 2, wherein the second bonding wire is electrically connected to a second bonding pad set on the die with one of the at least two bonding fingers.

4. The common assembly substrate according to claim 3, wherein the first bonding wire and the second bonding wire are connected to the same bonding finger.

5. The common assembly substrate according to claim 3, wherein the first bonding wire and the second bonding wire are respectively connected to two of the bonding fingers different from each other.

6. The common assembly substrate according to claim 3, further comprising a third bonding wire for electrically connecting the second bonding pad with one of the bonding fingers.

7. The common assembly substrate according to claim 6, wherein two of the at least two bonding fingers are electrically connected to each other by a fourth bonding wire.

8. The common assembly substrate according to claim 1, further comprising a power ring and a ground ring adjacent to the die, each of which is separated from the die and the bonding fingers.

9. A package structure, comprising:
a die;
a common assembly substrate for carrying the die;
a plurality of bonding fingers formed on one side of the common assembly substrate; and
a first bonding wire for electrically connecting a first bonding pad set on the die with one of the bonding fingers, wherein at least two of the bonding fingers are respectively intersected with an predetermined extension direction of the first bonding wire extended from the die.

10. The package structure according to claim 9, further comprising a second bonding wire, wherein at least two of the bonding fingers are respectively intersected with an predetermined extension direction of the second bonding wire extended from the die.

11. The package structure according to claim 10, wherein the second bonding wire is electrically connected to a second bonding pad set on the die with one of the at least two bonding fingers.

12. The package structure according to claim 11, wherein the first bonding wire and the second bonding wire are connected to the same bonding finger.

13. The package structure according to claim 11, wherein the first bonding wire and the second bonding wire are respectively connected to two of the bonding fingers different from each other.

14. The package structure according to claim 11, further comprising a third bonding wire for electrically connecting the second bonding pad with one of the bonding fingers.

15. The package structure according to claim 14, wherein two of the at least two bonding fingers are electrically connected to each other by a fourth bonding wire.

16. A package structure, comprising:
a die;
a common assembly substrate for carrying the die;
a plurality of bonding fingers formed on one side of the common assembly substrate;
a first bonding wire for electrically connecting a first bonding pad set on the die with one of the bonding fingers, wherein at least two of the bonding fingers are respectively intersected with an predetermined extension direction of the first bonding wire extended from the die;
a second bonding wire for electrically connecting a second bonding pad set on the die with one of the bonding fingers;
a third bonding wire for electrically connecting the second bonding pad with one of the bonding fingers; and
a fourth bonding wire for electrically connecting at least two of the bonding fingers.

17. A common assembly substrate for carrying a die, comprising:
a die attaching area formed on one side of the common assembly substrate; and
a plurality of bonding fingers formed on the common assembly substrate adjacent to an edge of the die attaching area, wherein the bonding fingers are parallel to one another, and a predetermined extension direction of the bonding fingers defines an included angle with the edge of the die attaching area in a range from about 0° to 165°.

18. The common assembly substrate according to claim 17, further comprising a power ring and a ground ring at least formed between the die attaching area and the bonding fingers.

19. The common assembly substrate according to claim 17, wherein the bonding fingers are rectangular pads arranged in a staggered matrix along the predetermined extension direction of the bonding fingers.
